(19) United States
(12) Patent Application Publication
(10) Pub. No.: US 2026/0238227 A1
(43) Pub. Date: Aug. 13, 2026

(54) WEIGHT COMPRESSION METHOD FOR AI MODELS

(71) Applicant: MEDIATEK INC., Hsinchu City (TW)

(72) Inventors: Sheng-Hui WANG, Hsinchu City (TW); Jeng-Yun HSU, Hsinchu City (TW); Chien-Hung LIN, Hsinchu City (TW)

(21) Appl. No.: 19/531,888

(22) Filed: Feb. 6, 2026

Related U.S. Application Data
(60) Provisional application No. 63/755,366, filed on Feb. 7, 2025.

(51) Int. Cl. H03M 7/40

(52) U.S. Cl. CPC H03M 7/40

(57) ABSTRACT

A lossless weight compression method for an Artificial Intelligence (AI) model having a plurality of weights is disclosed. The lossless weight compression method comprises the following steps: processing the plurality of weights as at least one sequence of symbols; and encoding the at least one sequence of symbols as at least one sequence of codewords with variable lengths; wherein the number of the codewords is smaller than that of the symbols; and wherein one of the codewords is an escape codeword representing that the corresponding symbols were stored without being encoded.

### CROSS-REFERENCE TO RELATED APPLICATIONS

The present Application claims the benefit of U.S. Provisional Patent Application Ser. No. 63/755,366 filed on February 7, 2025, the entire disclosure of which is incorporated herein in its entirety by reference.

### BACKGROUND OF THE INVENTION

### 1. Field of the Invention

This disclosure generally relates to weights of an Artificial Intelligence (AI) model, and more particularly, to a weight compression/decompression method for the AI model.

### 2. Description of Related Art

With the booming of artificial intelligence (AI) technology, AI deployment generally involves collecting centralized data and then using centralized servers or data centers with powerful computing capabilities to train AI models. Users can remotely connect with the centralized servers or data centers through internet. Users collect local data and send the data to the centralized servers or data centers, and then wait for the centralized servers or data centers to send back the decision or inference which is made by using the trained AI models. However, when it comes to sensors or Internet of Things (IoT) devices typically locating on the edge of the network (also known as edge devices), latency and security issues are concerned.

Edge AI is proposed for directly deploying AI models and AI algorithms onto the edge devices, which enables local data collection, real time decision-making, and localized machine learning without sending data to the centralized servers or data centers.

However, there are several challenges for the edge devices to deploy, run and train AI models, such as Large Language Model (LLM) with numerous parameters, including weights of AI models. For example, a smart phone is typically equipped with 6 GB, 8 GB or 12 GB DRAM. However, deploying LLamA2 7B released by META in INT8 mode requires at least 7 GB of DRAM, which is large memory footprint problem for the smart phone. In addition, running LLM, especially when running full connected (FC) operation, heavily relies on memory access for computational performance. When processing speed of Processor is much higher than the transferring speed of data of DRAM in the smart phone due to bandwidth limitation of DRAM, substantial time is spent not on computation itself but waiting for data to be saved in or loaded from DRAM, which is called as memory bound problem or memory wall problem.

Accordingly, a good weight compression/decompression method is needed, which can mitigate the aforementioned memory footprint, memory bound and memory wall problem.

### SUMMARY OF THE INVENTION

Given the above, in one aspect of the present disclosure, a lossless weight compression method for an Artificial Intelligence (AI) model having a plurality of weights is proposed. The lossless weight compression method comprises the following steps: processing the plurality of weights as at least one sequence of symbols; and encoding the at least one sequence of symbols as at least one sequence of codewords with variable lengths; wherein the number of the codewords is smaller than that of the symbols; and wherein one of the codewords is an escape codeword representing that the corresponding symbols were stored without being encoded.

In another aspect of the present disclosure, a weight compression method for an AI model having a plurality of weights is proposed. The weight compression method comprises the following steps: clustering the plurality of weights into a predetermined number of groups based on values of the plurality of weights, wherein each weight in the same group is given the same value to generate another plurality of weights; processing the another plurality of weights as at least one sequence of symbols; and encoding the at least one sequence of symbols as at least one sequence of codewords with variable lengths.

In yet another aspect of the present disclosure, a device with deployment of an AI model having a plurality of weights is proposed. The device comprises a compression unit, receiving the plurality of weights of the AI model and generating compression information of the AI model, wherein compression information is a Huffman tree (also known as Huffman table) representing the relationship between symbols and codewords; an AI compiler, coupled with the compression unit for receiving the plurality of weights of the AI model and the compression information and generating compression weights of the AI model containing at least one sequence of codewords with variable lengths in accordance with the compression information and also generating instructions; an AI hardware, coupled with the AI compiler for receiving the instructions; and a memory, coupled with the AI hardware and the AI compiler for storing temporary data sent from the AI hardware and the AI compiler during computations in connection with the compression weights of the AI model.

In yet another aspect of the present disclosure, a weight decompression method for an AI model having a plurality of weights is proposed. The weight decompression method comprises the following steps: receiving compression information and at least one sequence of compressed weights containing codewords with variable lengths; decompressing the codewords to generate at least one sequence of weights based on the compression information; and processing the at least one sequence of weights as the plurality of weights of the AI model; wherein the number of the codewords is smaller than that of the symbols and wherein one of the codewords is an escape codeword representing that the corresponding symbols were stored without being encoded.

These and other features and advantages of the present disclosure can be more readily understood from the following preferred embodiments with reference to the appended drawings.

### BRIEF DESCRIPTION OF THE DRAWINGS

In order to sufficiently understand the essence, advantages and the preferred embodiments, the following detailed description will be more clearly understood by referring to the accompanying drawings.

FIG. 1 illustrates a weight compression method for an AI model in accordance with a first embodiment of the present disclosure.

FIG. 2 illustrates a weight compression method for an AI model in accordance with a second embodiment of the present disclosure.

FIG. 3 illustrates a device with deployment of an AI model in accordance with a third embodiment of the present disclosure.

FIG. 4 illustrates a weight compression method for an AI model in accordance with the fourth embodiment of the present disclosure.

FIG. 5 illustrates a weight decompression method for an AI model in accordance with the fifth embodiment of the present disclosure.

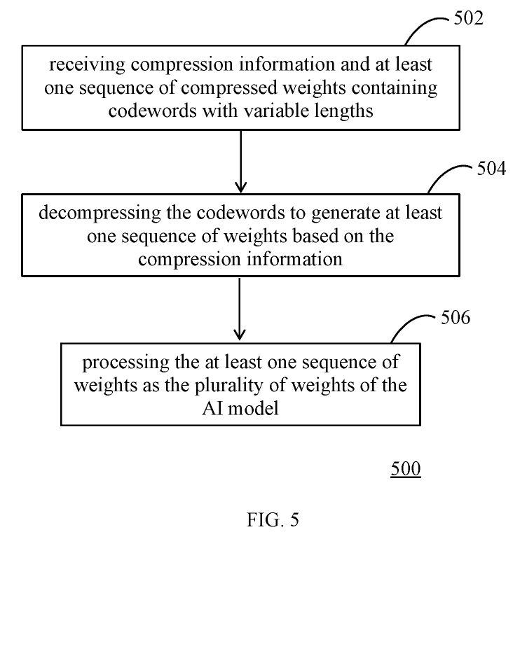

### DETAILED DESCRIPTION OF THE DRAWINGS

The following description discloses the preferred embodiments. The present disclosure is described below by referring to the embodiments and the figures. Thus, the present disclosure is not intended to be limited to the embodiments shown, but is to be accorded the principles disclosed herein. Furthermore, that various modifications or changes in light thereof will be suggested to those having ordinary skill in the art and are to be included within the spirit and purview of this application and scope of the appended claims.

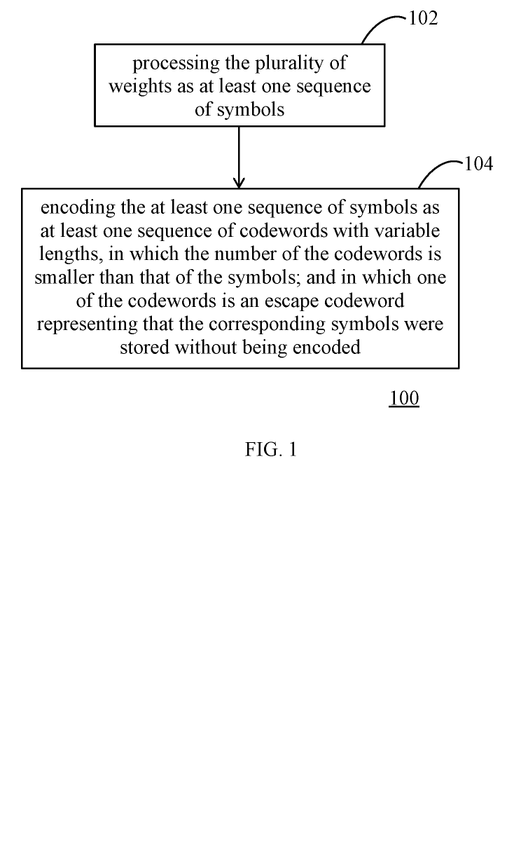

AI models, such as Large Language Model (LLM), can be built on a type of neural network (NN) architecture with numerous neurons and parameters, including weights and biases. In order to reduce amount of data transferred in an edge device having an internal DRAM, such as a smart phone, a cellular phone, an IoT device, etc., a weight compression method (100) for an AI model in accordance with the first embodiment of the present disclosure is proposed as shown in FIG. 1. The AI model is built on a type of neural network (NN) architecture having a plurality of weights. The weight compression method (100) comprises the following steps: processing the plurality of weights a s at least one sequence of symbols (step 102); and encoding the at least one sequence of symbols as at least one sequence of codewords with variable lengths (step 104), in which the number of the codewords is smaller than that of the symbols; and in which one of the codewords is an escape codeword representing that the corresponding symbols were stored without being encoded.

In the step 102, the plurality of weights can be processed as one sequence of weights or more than one sequence of weights. For example, the plurality of weights can be fragmented as 4 sequences of weights, which are also known as 4 subsequences of weights. Each subsequence of weights can be compressed and encoded parallelly and individually at the step 104. In one example, the 4 subsequences of weights are treated as subsequence of weights A, B, C and D, and further treated as subsequence of symbols A, B, C and D. In order to parallelly and individually compress/decompress and encode/decode the subsequence of symbols A, B, C and D, base information and read/write points in association with the subsequence of symbols A, B, C and D during compressing and encoding procedures are needed to be stored and maintained in internal buffers of the DRAM of the edge device, which indicating the order of compressed and encoded weights in association with the subsequence of symbols A, B, C and D which can be used for decompression and decoding. In another example, a bit rate control mechanism is adopted to arrange the compressed/encoded weights. In order to parallelly and individually compress/decompress and encode/decode the subsequence of symbols A, B, C and D, 2bit labels in association with the subsequence of symbols A, B, C and D during compressing and encoding procedure is needed to be stored and maintained for distinguishing the subsequence of symbols A, B, C and D, which can be used for decompression and decoding.

In the step 104, the encoding means can be a Huffman coding, a Shannon-Fano coding, or an Exponential-Golomb coding, which encodes the at least one sequence of symbols as a sequence of codewords with variable lengths. In one example, one symbol is encoded into one codeword, which means the encoding process is performed on a symbol‑by‑symbol basis. In another example, multiple symbols are encoded into one codeword, which means the encoding process is performed on a multiple-symbol-to-single-codeword basis.

The Huffman coding is a lossless data compression algorithm that, by creating a Huffman tree, assigns shorter codewords to frequently occurring symbols and longer codewords to less frequent symbols, which creates an optimal variable-length prefix codeword set to minimize the overall data size.

The Shannon-Fano coding is also a lossless data compression algorithm that assigns codewords to symbols based on symbol’s relative frequency of occurrence. It creates variable-length prefix codeword by recursively dividing a sorted list of symbols into two halves with as equal probability as possible to minimize the overall data size.

The Exponential-Golomb coding is also a lossless data compression algorithm that assigns longer codewords to symbols with larger values. It also creates variable-length prefix codeword to minimize the overall data size.

In one extended example, a zero-value compression (ZVC) can be considered as a subset encoding means of the Huffman coding. The ZVC begins with choosing a sparse value (SV) from the at least one sequence of symbols, not necessarily to be zero, and then generating a header portion (HD) indicating where the SVs are in the at least one sequence of symbols and a compressed data portion (CD) containing the wights with non-SV value only, which represents symbols without being encoded and compressed. The ZVC can be considered as a Huffman tree with only one layer, where the codeword 0 represents HD and the codeword 1 represents CD.

In the step 104, the number of the codewords is a predetermined number which is decided based on hardware implementations of the weight compression method (100). For example, when the number of the symbols is 256, the number of the codewords can be chosen to be 24 under the condition that the edge device can search the whole candidates of codewords for decoding during one cycle of the hardware implementations of the edge device deployed with the AI model. The one cycle of the hardware implementations for a current smart phone is about 1ns or less than 1ns in connection with the high-frequency clock in modern processor chip, which allows the whole codewords to be compared in one cycle for decoding.

In the step 104, one of the codewords is reserved as an escape codeword representing that the corresponding symbols were stored without being encoded. As such, when the number of the codewords is chosen to be 24, 23 codewords are used to represent their corresponding symbols and 1 escape codeword is used to represent its corresponding symbols were stored in their original values.

In the step 104, the number of the codewords is determined based on distributions of the values of the plurality of weights. For example, though the predetermined number of codeword is set to be 24 based on the hardware implementations for the current smart phone, only fewer codewords are used to encode symbols. For example, when only 18 values are found to be present in the sequence of symbols, 19 codewords are sufficient for use where one codeword is the escape codeword.

In one extended embodiment, the weight compression method (100) can further comprise the following step: performing a zero-value compression (ZVC) on a header portion (HD) of the at least one sequence of codewords to generate another header portion (HD of ZVC of HD) and another compressed data portion (CD of ZVC of HD) for additional compression. Specifically, when the at least one sequence of codewords is generated based on another ZVC, the HD contains one or more codewords indicating where the SVs are in the at least one sequence of symbols. When the at least one sequence of codewords is generated based on the Huffman coding, the HD means the value of the top layer of the created Huffman tree. For example, if the at least one sequence of codewords is [0], [10], [110] and [111], which can be decoded/decompressed as the at least one sequence of symbols a, b, c and the escaped codeword in accordance with the Huffman tree, the HD of the first codeword is 0 and the HDs of the other codewords are 1. The 0 and 1 represent the information in association with the top layer of the Huffman tree.

Given the above, the weight compression method (100) adopts at least two lossless compression (or encoding) means to reduce transferring volume of weights so as to reduce the bandwidth of DRAM in the edge device, and thus enhance the computing performance of the edge device.

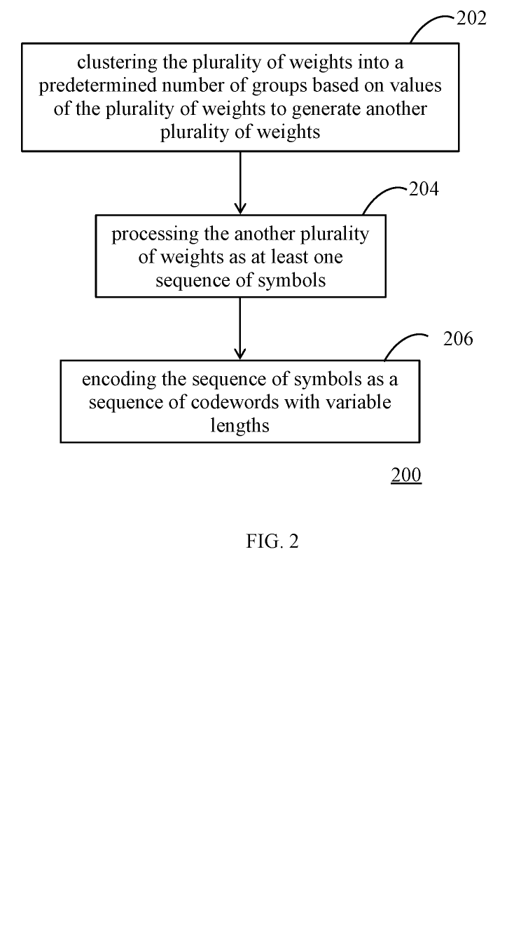

In order to reduce transferring amount of data in an edge device having internal DRAM, such as a smart phone, a cellular phone, an IoT device, etc., a weight compression method (200) for an AI model in accordance with the second embodiment of the present disclosure is proposed as shown in FIG. 2. The AI model is built on a type of neural network (NN) architecture having a plurality of weights. The weight compression method (200) comprises the following steps: clustering the plurality of weights into a predetermined number of groups based on values of the plurality of weights, wherein each weight in the same group is given the same value to generate another plurality of weights (step 202); processing the another plurality of weights as at least one sequence of symbols (step 204); and encoding the sequence of symbols as a sequence of codewords with variable lengths (step 206).

In the step 202, a cluster pruning means is adopted to reduce the number of weights in the NN of the AI model. The cluster pruning means begins with putting all values of weights in a selection list (step 202-1); marking all values of weights as not fixed (step 202-2); selecting one value of weight that has the highest occurrence frequency as a pruning target (step 202-3); pruning all values of weights not marked as fixed toward the pruning target (step 202-4), for example, changing the values of weights which are close the value of wight of pruning target to be the value of wight of pruning target so as to form a group where each weight in the group is given the same value; marking the value of wight of pruning target as fixed and then removing it from the selection list (step 202-5); checking whether the number of the group meets a predetermined number or not, and if no, going to step 202-1, and if yes, finishing the cluster pruning means. By adoption of the aforementioned cluster pruning means, all values of weights can be clustered into a predetermined number of groups based on values of weights, where each weight in the same group is given the same value. For example, the value of weight ranged from 0 – 255 in 8bit can be cluster pruned to 24 groups named from group 1 – 24, where 24 is the predetermined number of groups and each value of weight in group 1 is given the same value, and so forth. By reducing the number of parameters in the NN of the AI model through pruning part of weights, it can effectively reduce the NN’s storage footprint, which can further diminish the computational cost and energy requirement during the training or inference process of the AI model. The cluster pruning means focuses on trimming away parts of weights in the NN of the AI model which contribute little to the overall performance of the AI model.

Step 204 and step 206 are similar steps with step 102 and step 104. Please refer to the description related to step 102 and step 104, which is omitted here.

Given the above, the weight compression method (200) adopts lossy cluster pruning means to reduce the number of the values of weights so as to reduce the usage of codewords and the usage of the bandwidth of the DRAM in the edge device, and thus enhance the computing performance of the edge device.

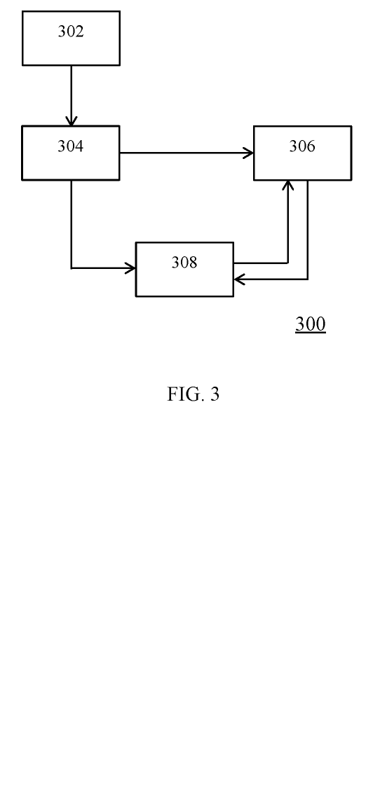

In order to reduce transferring amount of data in association with an AI model needed to be processed in a device having internal DRAM, etc., a device (300) with deployment of an AI model having a plurality of weights in accordance with the third embodiment of the present disclosure is proposed as shown in FIG. 3. The device (300) can be an edge device, such as a smart phone, a cellular phone, an IoT device. The device (300) comprises a compression unit (302), an AI compiler (304), an AI hardware (306) and a DRAM (308). The compression unit (302) receives the plurality of weights of the AI model and then generates compression information in association with the weights of the AI model. The AI compiler (304), coupled with the compression unit (302), receives the plurality of weights of AI model and the compression information in association with the AI model and then generates compressed weights of AI model in accordance with the compression information in association with the AI model containing at least one sequence of codewords with variable lengths and then also generates instructions. The AI hardware (306), coupled with the AI compiler (304), receives the instructions sent from the AI compiler (304). The memory (308), coupled with the AI hardware (306) and the AI compiler (304), stores temporary data sent from the AI hardware (306) and the AI compiler (304) during computations in connection with the compression weights of the AI model. The temporary data includes the compressed weights of AI model and the compression information.

The compression unit (302) can generate the compression information representing the relationship between symbols and codewords. For example, the compression information can be is a Huffman tree (also known as Huffman table) representing a corresponding table of symbols and codewords in accordance with the aforementioned weight compression method (100) or the weight compression method (200). The AI compiler (304) generates one sequence of compressed/encoded weights of the AI model, or more than one subsequence of compressed/encoded weights of the AI model with the information of compressing/encoding order (pointers or labels) in association with the subsequences of compressed/encoded weights. The information of compressing/encoding order can be deemed as compression information as well. The AI hardware (306) reads the compressed weights of AI model and the compression information from the memory (308) and decompress/decode the compressed weights of AI model in accordance with the compression information, such as the relationship between symbols and codewords and/or compressing/encoding order (pointers or labels) in association with the subsequences of compressed/encoded weights.

The memory (308) can be DDR4 DRAM, DDR5 DRAM, LPDDR4 DRAM, LPDDR5 DRAM, SDRAM or other suitable memory.

Given the above, the device (300) adopts lossless compressing and encoding means or lossy cluster pruning means with lossless compressing and encoding means to reduce the usage of the bandwidth of the memory (308) in the device (300), and thus enhance the computing performance of the device (300).

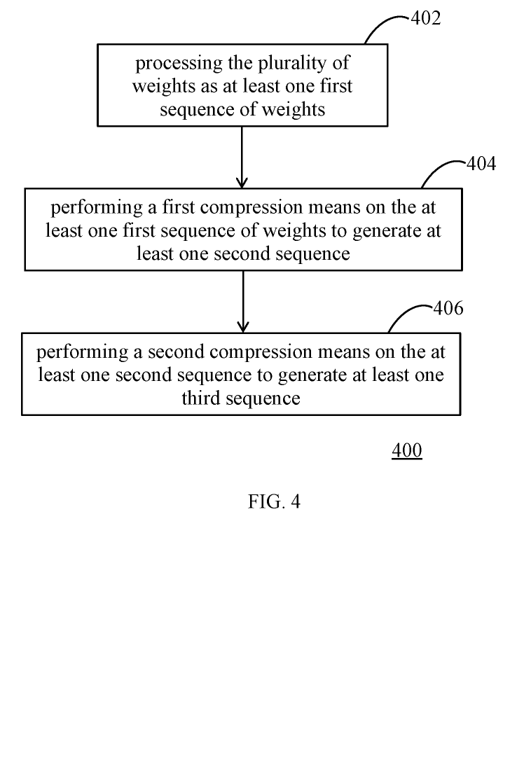

In order to reduce transferring amount of data in an edge device having internal DRAM, such as a smart phone, a cellular phone, an IoT device, etc., a weight compression method (400) for an AI model in accordance with the fourth embodiment of the present disclosure is proposed as shown in FIG. 4. The AI model is built on a type of neural network (NN) architecture having a plurality of weights.

The weight compression method (400) in accordance with the fourth embodiment of the present disclosure is an extended embodiment of the first and second embodiments. The description for similar steps is omitted here for simplicity. Please also refer to the description made for the first and second embodiments.

The weight compression method (400) comprises the following steps: processing the plurality of weights as at least one first sequence of weights (step 402); performing a first compression means on the at least one first sequence of weights to generate at least one second sequence (step 404); and performing a second compression means on the at least one second sequence to generate at least one third sequence (step 406), wherein one of the first compression means and the second compression means uses codewords with variable lengths to represent symbols in the at least one first sequence or the at least one second sequence; and wherein the number of the codewords is smaller than that of the symbols.

In the step 402 and step 404, the first compression means can be a zero-value compression means and the second compression means can be a Huffman coding means, a Shannon-Fano coding means, or an Exponential-Golomb coding means. Please note that those having ordinary skill in the art would understand that a coding means may be a compression means if the coded sequence is shorter than the uncoded sequence.

In the step 404, the Huffman coding means, the Shannon-Fano coding means, or the Exponential-Golomb coding means is used to encode the second sequence containing the symbols as the third sequence containing the codewords with variable lengths on a symbol‑by‑symbol basis.

In the step 404, the Huffman coding means, the Shannon-Fano coding means, or the Exponential-Golomb coding means is used to encode the second sequence containing the symbols as the third sequence containing the codewords with variable lengths from multiple symbols into a single codeword.

In the step 402, the first sequence containing a head portion, and wherein a third compression means is performed on the head portion of the first sequence for further compression. The third compression means can be a zero-value compression means, a Huffman coding means, a Shannon-Fano coding means, or an Exponential-Golomb coding means.

In the step 402 and step 404, the first compression means can be a Huffman coding means, a Shannon-Fano coding means, or an Exponential-Golomb coding means and the second compression means can be the Huffman coding means, the Shannon-Fano coding means, or the Exponential-Golomb coding means.

In the step 402 and step 404, the first compression means can be a Huffman coding means, a Shannon-Fano coding means, or an Exponential-Golomb coding means and the second compression means can be a zero-value compression means.

The preferred embodiments of the present invention have been described above. However, those having ordinary skill in the art readily recognize that the disclosure described above can be utilized in a variety of devices, environments, and situations. Although the present invention is written with respect to specific embodiments and implementations, various changes and modifications may be suggested to those having ordinary skill in the art. It is intended that the present disclosure encompasses such changes and modifications that fall within the scope of the appended claims.

For instance, those having ordinary skill in the art would understand that though the number of the codewords and the number of groups are illustrated as 24 in accordance with the aforementioned embodiments, the number of the codewords and the number of groups can be set as a predetermined number lower or higher than 24 based on the hardware implementation of the embodiments.

For instance, those having ordinary skill in the art would understand that compressing/encoding and decompressing/decoding are two sides of the same coin. Accordingly, on one hand, original weights of an AI model can be compressed/encoded by using the compressing/encoding procedures disclosed in the weight compression method (100) and the weight compression method (200). On the other hand, the compressed/encoded weights can be decompressed/decoded back to the original weights of the AI model in a reversed manner.

Accordingly, a weight decompression method (500) for an AI model having a plurality of weights in accordance with the fifth embodiment of the present disclosure is also proposed. The weight decompression method (500) comprises the following steps: receiving compression information and at least one sequence of compressed weights containing codewords with variable lengths (step 502); decompressing the codewords to generate at least one sequence of weights based on the compression information (step 504); and processing the at least one sequence of weights as the plurality of weights of the AI model (step 506); and wherein the number of the codewords is smaller than that of the symbols and wherein one of the codewords is an escape codeword representing that the corresponding symbols were stored without being encoded.

In the step 502, the compression information can be a header portion (HD) in association with the at least one sequence of symbols generated during a zero-value compression (ZVC) procedure or a Huffman coding procedure. Please refer to the description made for the first and second embodiments for the ZVC procedure in details.

In the step 502, the number of the codewords is smaller than that of the symbols and one of the codewords is an escape codeword representing that the corresponding symbols were stored without being encoded. Please refer to the description made for the first and second embodiments for the relationship between symbols and codewords in details.

In the step 502, the compression information containing a compressing order in association with the at least one sequence of compressed weights. The compressed information can be used to parallelly and individually decompress/decode the at least one sequence of compressed weights.

In addition, in one extended embodiment, there can be no escape codeword used in a lossless weight compression method in accordance with the present disclosure. The lossless weight compression method for an AI model having a plurality of weights comprises the following steps: processing the plurality of weights as at least one sequence of symbols; and encoding the at least one sequence of symbols as at least one sequence of codewords with variable lengths; wherein the number of the codewords is smaller than that of the symbols; and wherein the number of the codewords is determined based on distributions of the values of the plurality of weights. For example, when only 18 values are found to be present in the sequence of symbols, 18 codewords are sufficient for lossless compression/encoding without the usage of the escape codeword.

What is claimed is:

1. A lossless weight compression method for an Artificial Intelligence (AI) model having a plurality of weights, comprising the following steps:
processing the plurality of weights as at least one sequence of symbols; and
encoding the at least one sequence of symbols as at least one sequence of codewords with variable lengths;
wherein the number of the codewords is smaller than that of the symbols; and
wherein one of the codewords is an escape codeword representing that the corresponding symbols were stored without being encoded.

2. The lossless weight compression method of claim 1, wherein a Huffman coding, a Shannon-Fano coding, or an Exponential-Golomb coding is used to encode the at least one sequence of symbols as the at least one sequence of codewords with variable lengths on a symbol‑by‑symbol basis.

3. The lossless weight compression method of claim 1, wherein a Huffman coding, a Shannon-Fano coding, or an Exponential-Golomb coding is used to encode the at least one sequence of symbols as the at least one sequence of codewords with variable lengths from multiple symbols into a single codeword.

4. The lossless weight compression method of claim 1, wherein the number of the codewords is a predetermined number which is decided based on hardware implementations of the lossless weight compression method.

5. The lossless weight compression method of claim 1, wherein the number of the codewords is determined based on distributions of the values of the plurality of weights.

6. The lossless weight compression method of claim 1, wherein a Huffman coding is used to encode the at least one sequence of symbols as the at least one sequence of codewords with variable lengths having a header portion, and wherein the lossless weight compression method further comprises performing a zero-value compression on the header portion.

7. The lossless weight compression method of claim 1, wherein a Huffman coding is used to encode the at least one sequence of symbols as the at least one sequence of codewords with variable lengths having a header portion, and wherein the lossless weight compression method further comprises encoding the header portion as another sequence of codewords with variable lengths.

8. The lossless weight compression method of claim 7, wherein a Huffman coding, a Shannon-Fano coding, or an Exponential-Golomb coding is used to encode the header portion as the another sequence of codewords with variable lengths.

9. A weight compression method for an AI model having a plurality of weights, comprising the following steps:
clustering the plurality of weights into a predetermined number of groups based on values of the plurality of weights, wherein each weight in the same group is given the same value to generate another plurality of weights;
processing the another plurality of weights as at least one sequence of symbols;
encoding the at least one sequence of symbols as at least one sequence of codewords with variable lengths.

10. The weight compression method of claim 9, wherein the number of the codewords is smaller than that of the symbols.

11. The weight compression method of claim 9, wherein one of the codewords is an escape codeword representing that the corresponding symbols were not encoded.

12. The weight compression method of claim 9, wherein a Huffman coding, a Shannon-Fano coding, or an Exponential-Golomb coding is used to encode the at least one sequence of symbols as the at least one sequence of codewords with variable lengths on a symbol‑by‑symbol basis.

13. The weight compression method of claim 9, wherein a Huffman coding, a Shannon-Fano coding, or an Exponential-Golomb coding is used to encode the at least one sequence of symbols as the at least one sequence of codewords with variable lengths from multiple symbols into a single codeword.

14. The weight compression method of claim 9, wherein the predetermined number of groups is determined based on hardware implementations of the weight compression method.

15. The weight compression method of claim 9, wherein the number of the codewords is a predetermined number which is determined based on hardware implementations of the weight compression method.

16. The weight compression method of claim 9, wherein the number of the codewords is determined based on distributions of the values of the plurality of weights or the values of the another plurality of weights.

17. The weight compression method of claim 9, wherein a Huffman coding is used to encode the at least one sequence of symbols as the at least one sequence of codewords with variable lengths having a header portion, and wherein the lossless weight compression method further comprises performing a zero-value compression on the header portion.

18. The weight compression method of claim 9, wherein a Huffman coding is used to encode the at least one sequence of symbols as the at least one sequence of codewords with variable lengths having a header portion, and wherein the lossless weight compression method further comprises encoding the header portion as another sequence of codewords with variable lengths.

19. The weight compression method of claim 18, wherein a Huffman coding, a Shannon-Fano coding, or an Exponential-Golomb coding is used to encode the header portion as the another sequence of codewords with variable lengths.

20. A lossless weight compression method for an Artificial Intelligence (AI) model having a plurality of weights, comprising the following steps:
processing the plurality of weights as at least one sequence of symbols; and
encoding the at least one sequence of symbols as at least one sequence of codewords with variable lengths;
wherein the number of the codewords is smaller than that of the symbols; and
wherein the number of the codewords is determined based on distributions of the values of the plurality of weights.
